(19) United States
(12) Patent Application Publication
(10) Pub. No.: US 2011/0167323 A1
(43) Pub. Date: Jul. 7, 2011

(54) Error-Correcting Apparatus and Method Thereof

(75) Inventors: Chih-Ching Yu, Hsinchu City (TW); Pi-Hai Liu, Zhubei City (TW); Yu-Hsuan Lin, Taichung City (TW); Chang-Long Wu, Hsinchu City (TW); Hong-Ching Chen, Fang-Shan City (TW)

(73) Assignee: MEDIATEK INC., Hsin-Chu (TW)

(21) Appl. No.: 12/683,915

(22) Filed: Jan. 7, 2010

(51) Int. Cl. H03M 13/41; G06F 11/10

(52) U.S. Cl. 714/795; 714/E11.032

(57) ABSTRACT

The invention discloses an error-correcting apparatus for decoding an input signal by using a Viterbi algorithm to generate a Viterbi-decoded signal, including an erasure unit and a decoder. The erasure unit is configured to generate at least one logic signal according to at least one path metric difference of path metrics in the Viterbi algorithm, and generate erasure information, wherein the erasure information indicates data reliability of at least one location of the Viterbi-decoded signal. The decoder is configured to decode the Viterbi-decoded signal according to the erasure information.

### BACKGROUND OF THE INVENTION

1. Field of the Invention

The invention relates generally to an error-correcting apparatus and method, and more particularly, to an error-correcting apparatus and method using a Viterbi algorithm.

2. Description of the Related Art

FIG. 1 depicts a diagram of an optical disk system. In FIG. 1, the optical pickup unit 20 retrieves a radio frequency (RF) signal from an optical disk 10. The retrieved RF signal is then sent to a signal processing unit 30 for further processing. The processed signal is provided to an analog-to-digital converter (ADC) 40 to be digitalized into a digital signal. The digital signal is sent to a phase loop lock (PLL) processing unit 50 and a finite impulse response (FIR) equalizer 60. The FIR equalizer 60 performs an equalization operation on the received signal and outputs an equalized signal to a Viterbi detector 70 for data decoding. The Viterbi detector 70 decodes the received signal according to a plurality of target levels thereof and generates a Viterbi-decoded signal Viterbi_out. The Viterbi-decoded signal Viterbi_out is then decoded by a decoder 80 for output as final data.

Generally, an error rate is assumed for the Viterbi detector 70 when decoding signals. In such a case, when the error rate is too large, the results of the decoded signal is inaccurate.

### BRIEF SUMMARY OF THE INVENTION

In light of the problem, there exists a need to improve the error-correcting ability of the Viterbi detector.

An embodiment of the invention discloses an error-correcting apparatus for decoding an input signal by using a Viterbi algorithm to generate a Viterbi-decoded signal, comprising an erasure unit and a decoder. The erasure unit is configured to generate at least one logic signal according to at least one path metric difference of path metrics in the Viterbi algorithm, and generate erasure information, wherein the erasure information indicates data reliability of at least one location of the Viterbi-decoded signal. The decoder is configured to decode the Viterbi-decoded signal according to the erasure information.

An embodiment of the invention discloses an error-correcting apparatus for decoding an input signal by using a Viterbi algorithm to generate a Viterbi-decoded signal, comprising an erasure unit and a decoder. The erasure unit is configured to generate erasure information according to a plurality of logic signals from a chosen intermediate portion stage of a plurality of selector stages, wherein the plurality of logic signals are generated from a logic high signal and a logic low signal that are selectively output by the plurality of selector stages according to first and second decision bits, and the erasure information indicates data reliability of at least one location of the Viterbi-decoded signal. The decoder is configured to decode the Viterbi-decoded signal according to the erasure information.

An embodiment of the invention discloses an error-correcting apparatus, comprising a first detector, a second detector, a consistence check unit and a decoder. The first detector is configured to generate a first binary data according to an input signal. The second detector is configured to generate a second binary data according to the input signal. The consistence check unit is configured to generate erasure information by finding out at least one location where inconsistency between the first binary data and the second binary data has occurred, wherein the erasure information indicates data reliability of the at least one location of the first and second binary data. The decoder is configured to decode the first binary data according to the erasure information.

An embodiment of the invention discloses an error-correcting apparatus for data decoding of an optical disk, comprising a Viterbi detector, an erasure unit and a decoder. The Viterbi detector is configured to retrieve data from a predetermined location of the optical disk twice to obtain first and second input signals, and decode the first and second input signals to generate first and second binary data. The erasure unit is configured to generate erasure information by finding out at least one location where inconsistency between the first and second binary data has occurred, wherein the erasure information indicates data reliability of the at least one location of the first and second binary data. The decoder is configured to decode at least one of the first and second binary data according to the erasure information.

### BRIEF DESCRIPTION OF THE DRAWINGS

The invention can be more fully understood by reading the subsequent detailed description and examples with references made to the accompanying drawings, wherein:

FIG. 1 depicts a diagram of an optical disk system;

FIG. 2 depicts a diagram of a Viterbi decoding apparatus;

FIG. 3 depicts a diagram of a branch metric generator;

FIG. 4 depicts a diagram of an ACS unit;

FIG. 5 depicts a diagram of a survivor path memory;

FIG. 6 depicts a diagram of an error-correcting apparatus used for decoding an input signal, according to an embodiment of the invention;

FIG. 7 depicts a diagram of an ACS unit according to an embodiment of the invention;

FIG. 8 depicts a diagram of an erasure unit according to an embodiment of the invention;

FIG. 9 depicts a flowchart of an error-correcting method used for decoding an input signal according to an embodiment of the invention, which is performed in accordance with the error-correcting apparatus shown in FIG. 6;

FIG. 10 depicts a detailed flowchart of the step S96 for generating the erasure information, according to an embodiment of the invention;

FIG. 11 depicts a diagram of an error-correcting apparatus used for decoding an input signal, according to an embodiment of the invention;

FIG. 12 depicts a detailed circuit diagram of a survivor path memory along with an erasure unit coupled thereto, according to an embodiment of the invention;

FIG. 13 depicts a diagram for generating erasure information from a plurality logic signals, according to an embodiment of the invention;

FIG. 14 depicts a flowchart of an error-correcting method used for decoding an input signal according to an embodiment of the invention, which is performed in accordance with the error-correcting apparatus shown in FIG. 11;

FIG. 15 depicts a detailed flowchart of step S146 for generating the erasure information, according to an embodiment of the invention;

FIG. 16 depicts a diagram of an error-correcting apparatus used for decoding an input signal according to an embodiment of the invention;

FIG. 17 depicts a flowchart of an error-correcting method used for decoding an input signal according to an embodiment of the invention, which is performed in accordance with the error-correcting apparatus shown in FIG. 16;

FIG. 18 depicts a diagram of an error-correcting apparatus used for decoding an input signal according to an embodiment of the invention; and

FIG. 19 depicts a flowchart of an error-correcting method used for decoding an input signal according to an embodiment of the invention, which is performed in accordance with the error-correcting apparatus shown in FIG. 18.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

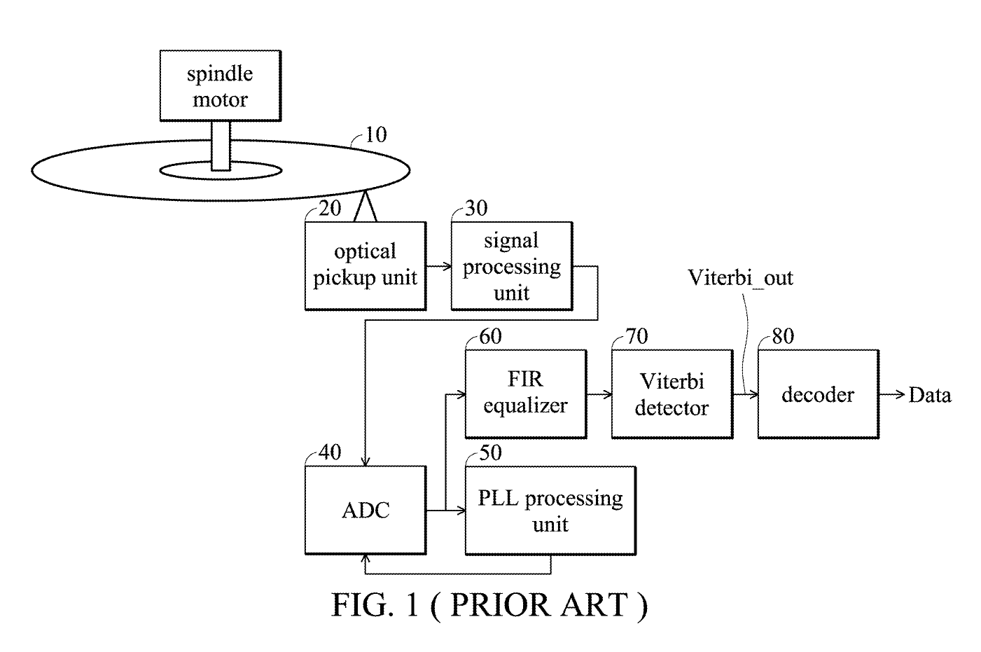

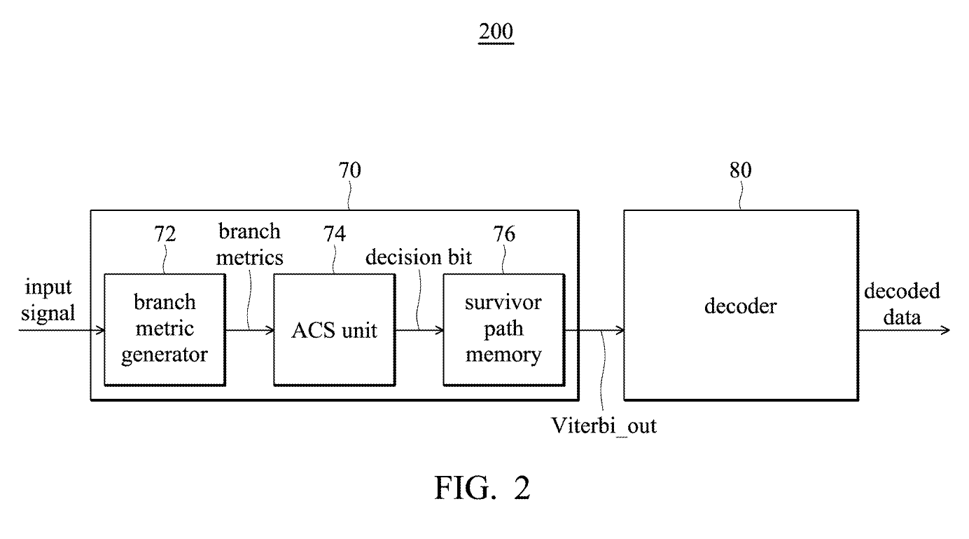

FIG. 2 depicts a diagram of a Viterbi decoding apparatus, comprising the Viterbi detector 70 and the decoder 80 of FIG. 1. The Viterbi detector 70 comprises a branch metric generator 72, an add-compare-select (ACS) unit 74 and a survivor path memory 76. The functionalities thereof will be described below.

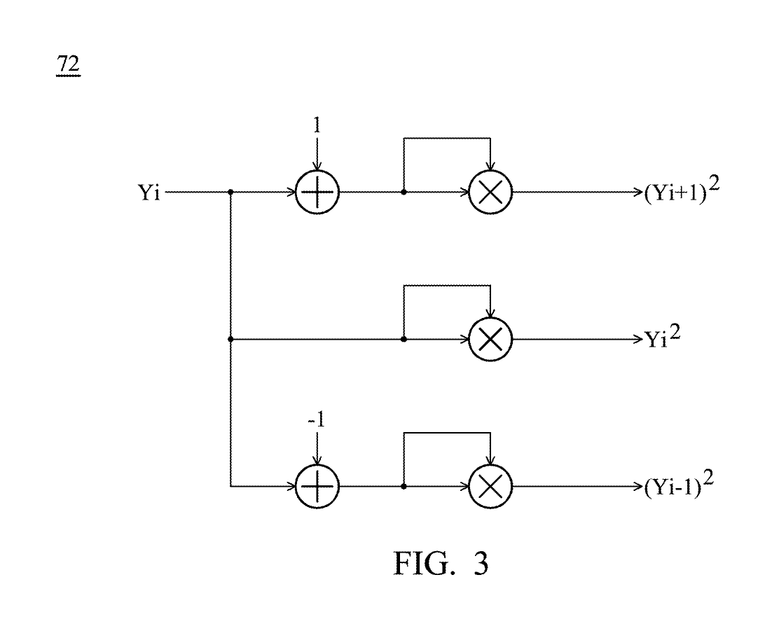

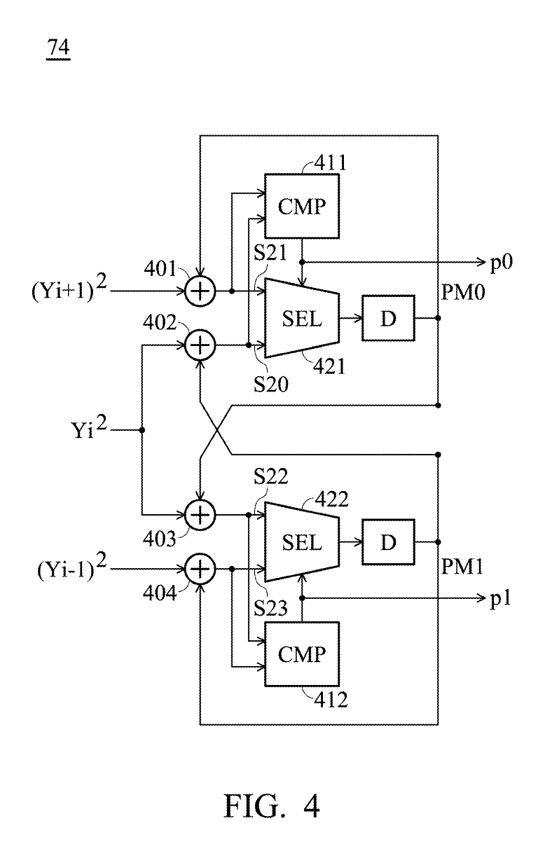

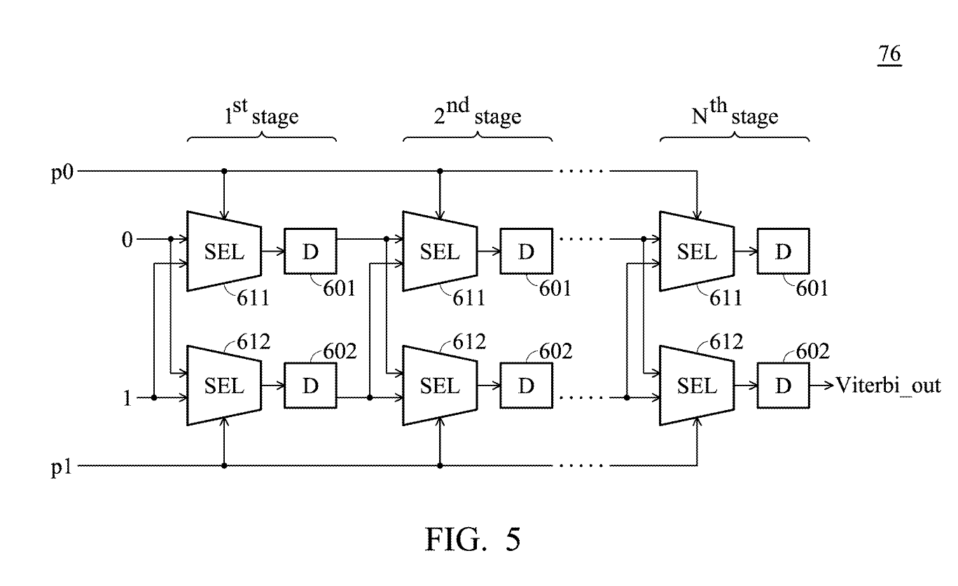

FIG. 3 depicts a diagram of a branch metric generator. In FIG. 3, an input signal Yi is received to generate branch metrics (Yi+1)², Yi² and (Yi−1)². The branch metrics are sent to the ACS unit 74 as shown in FIG. 2. FIG. 4 depicts a diagram of an ACS unit. In FIG. 4, the branch metrics (Yi+1)², Yi² and (Yi−1)² are received and used by the adders 401, 402, 403 and 404 to generate a plurality of path metrics S20, S21, S22 and S23. The path metrics S20, S21, S22 and S23 are compared by the comparator 411 and comparator 412 which respectively output a first decision bit P0 and a second decision bit P1 according to the comparison result thereof. The first decision bit P0 controls the selectors 421 to select one of the path metrics S20 and S21 as a path metric PM0, and the second decision bit P1 controls the selectors 422 to select one of the path metrics S22 and S23 as a path metric PM1. The first decision bit P0 and second decision bit P1 are sent to the survivor path memory 6. As shown in FIG. 5, the survivor path memory 76 comprises a plurality of selector stages (paths), each stage may comprise at least two selectors 611 and 612 and at least two registers 601 and 602. Initially, the first selector stage receives a logic high signal “1” and a logic low signal “0”, and each selector in the first stage respectively selects one of the logic signals as an output logic signal to be sent to a corresponding register 601/602, wherein the selection is made based on the first decision bit P0 and second decision bit P1. In particular, based on the first decision bit P0, the selector 611 in the first stage selects the logic high signal “1” or logic low signal “0” as an output logic signal to be stored in the register 601. Similarly, based on the second decision bit P1, the selector 612 in the first stage selects the logic high signal “1” or logic low signal “0” as an output logic signal to be stored in the register 602. The logic signals stored in the register 601 and register 602 in the first stage are treated by the second stage as the input logic signals. The second stage then works in the same manner as the first stage such that the initial logic high signal “1” and logic low signal “0” are selectively output stage-by-stage to generate the Viterbi-decoded signal Viterbi_out.

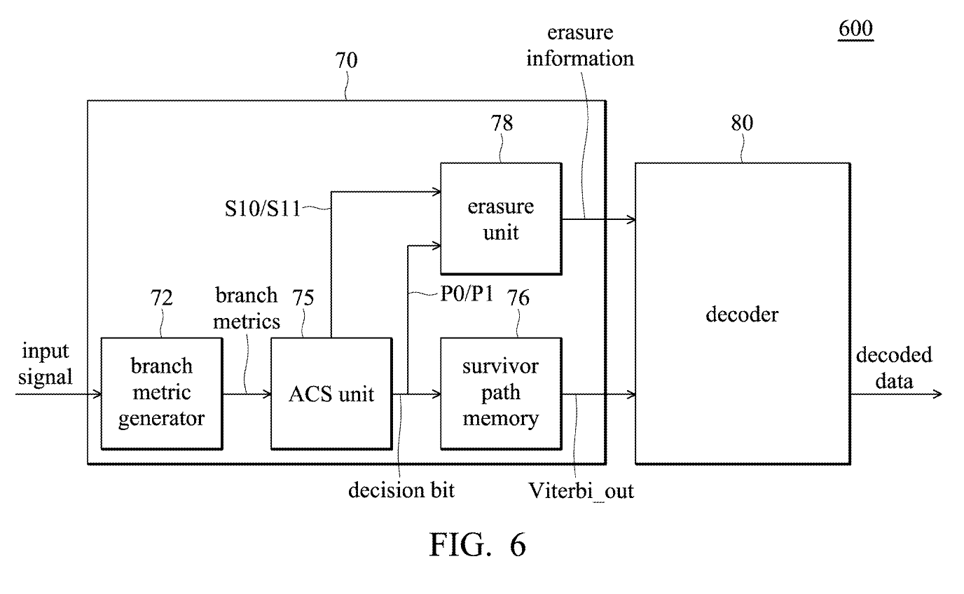

FIG. 6 depicts a diagram of an error-correcting apparatus used for decoding an input signal, according to an embodiment of the invention. The error-correcting apparatus 600 comprises a branch metric generator 72, an ACS unit 75, a survivor path memory 76, an erasure unit 78 and a decoder 80. The functionality of the branch metric generator 72 and the survivor path memory 76 are the same as the previous embodiment, so it is not described herein for brevity. The erasure unit 78 receives a first path metric difference S10, a second path metric difference S11, a first decision bit P0 and a second decision bit P1 from the ACS unit 75 and generates erasure information for the decoder 80. The decoder 80 decodes the Viterbi-decoded signal Viterbi_out based on the erasure information to generate the decoded data. The detailed operation of the ACS unit 75 and erasure unit 78 are described below.

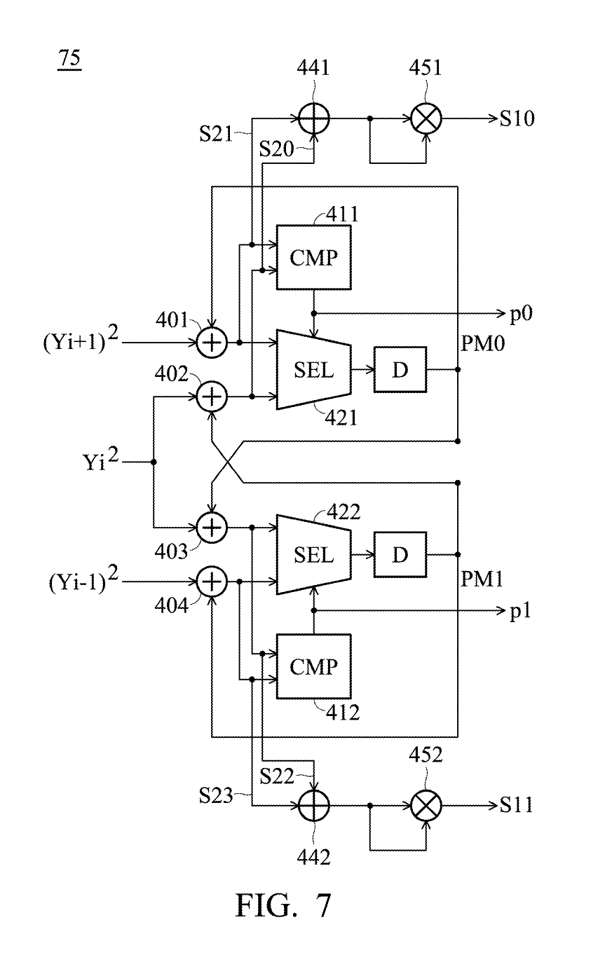

FIG. 7 depicts a diagram of an ACS unit according to an embodiment of the invention. In FIG. 7, the path metrics S20 and S21 are provided to a subtracter 441 which performs a subtraction operation on the path metrics S20 and S21 to calculate a difference therebetween (path metric difference). The calculated path metric difference, either positive or negative, is further sent to a multiplier 451 to determine a positive value thereof. The obtained positive value S10 is sent to the erasure unit 78 for further processing. Similarly, the path metrics S22 and S23 are provided to a subtracter 442 which performs a subtraction operation on the path metrics S22 and S23 to calculate a difference therebetween (path metric difference). The calculated path metric difference, either positive or negative, is further sent to a multiplier 452 to determine a positive value thereof. The obtained difference S11 is also sent to the reassure unit 78 for further processing. The multipliers 451 and 452 may also be an absoluter which performs an absolute operation on the path metric differences, or any other units capable of obtaining a positive result of the path metric differences.

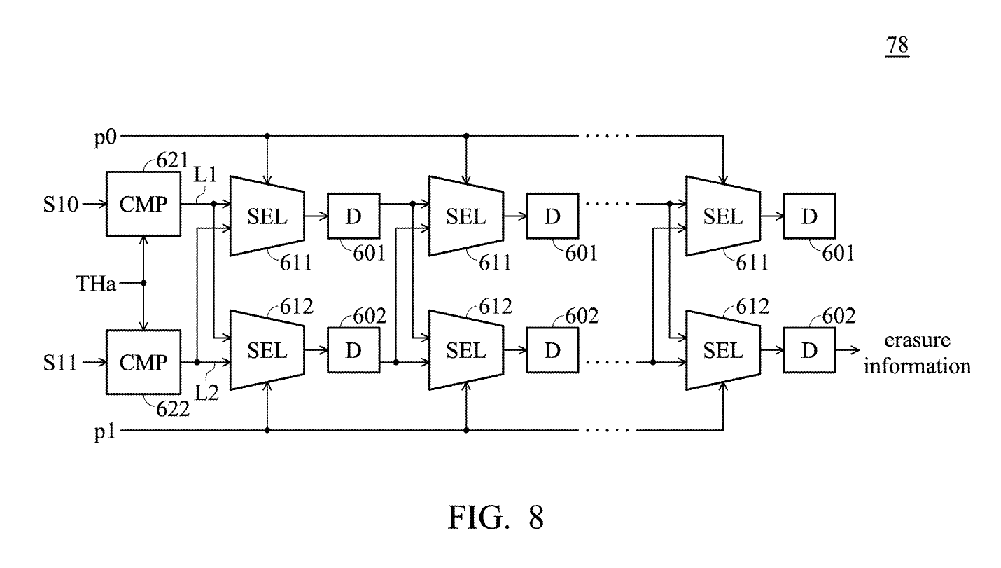

FIG. 8 depicts a diagram of an erasure unit according to an embodiment of the invention. In FIG. 8, the erasure unit 78 comprises at least two comparators 621 and 622 and a plurality of selector stages, each comprises at least two selectors 611 and 612 and two registers 601 and 611 as the survivor path memory 76. The path metric differences S10 and S11 (both positive) are provided as the input signals for the erasure unit 78. The comparator 621 compares the path metric difference S10 with a threshold value THa and generates a logic signal L1 according to the comparison result. If the path metric difference S10 is smaller than the threshold value THa, the output logic signal L1 will be logic high “1”, and vice versa. A logic high “1” output logic signal L1 results from the path metric difference S10 being smaller than the threshold value THa, which may suggest low data reliability of the Viterbi-decoded signal Viterbi_out. On the contrary, a logic low “0” output logic signal L1 results from the path metric difference S10 being larger than the threshold value THa, which may suggest high data reliability of the Viterbi-decoded signal Viterbi_out. Similarly, the comparator 622 compares the path metric difference S11 with the threshold value THa and generates a logic signal L2 according to the comparison result. If the path metric difference S11 is smaller than the threshold value THa, the output logic signal L2 will also be logic high “1”, and vice versa. Based on this, two logic signals L1 and L2 are output as the input logic signals for the first selector stages, and the logic signals L1 and L2 are selectively output by the plurality of selector stages according to the first decision bit P0 and second decision bit P1, thereby generating the erasure information. As described above, the decoder 80 decodes the Viterbi-decoded signal Viterbi_out based on the erasure information to generate the decoded data. It is noted that in the ACS unit 75 proposed by the invention, the subtracters 441 and 442 and the multipliers 451 and 452 may also be integrated into the erasure unit 78.

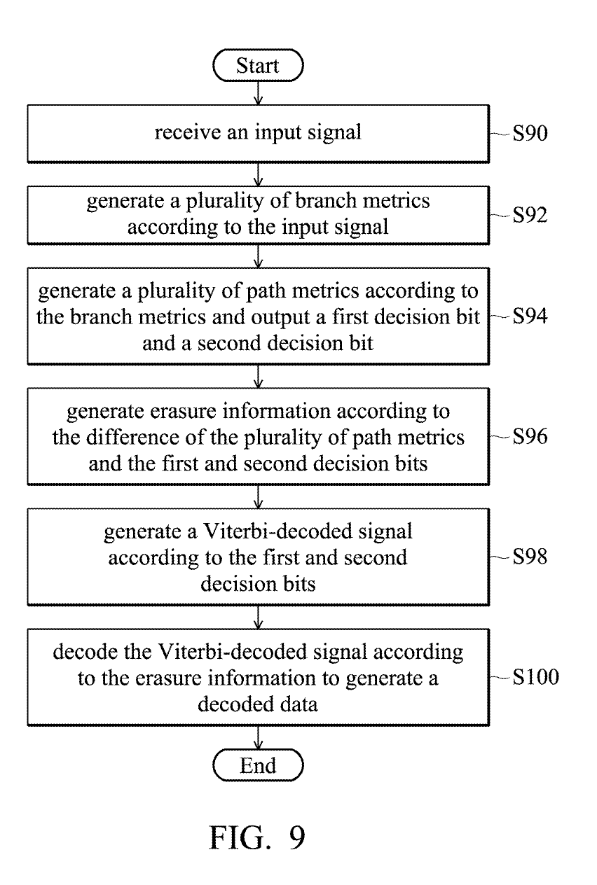

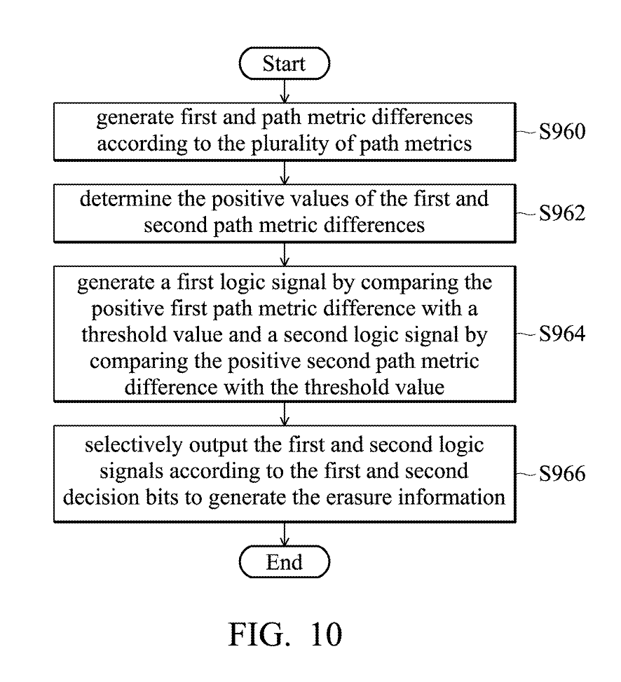

FIG. 9 depicts a flowchart of an error-correcting method used for decoding data that is received according to an embodiment of the invention, which is performed in accordance with the error-correcting apparatus shown in FIG. 6. At the beginning, an input signal is received (step S90). Next, a plurality of branch metrics are generated according to the input signal (step S92). Next, a plurality of path metrics are generated according to the branch metrics, and a first decision bit and a second decision bit are output (step S94). Next, erasure information is generated according to the difference of the plurality of path metrics and the first and second decision bits (step S96). Next, a Viterbi-decoded signal Viterbi_out is generated according to the first and second decision bits (step S98). Next, the Viterbi-decoded signal Viterbi_out is decoded according to the erasure information to generate a decoded data (step S100). FIG. 10 depicts a detailed flowchart of the step S96 for generating the erasure information, according to an embodiment of the invention. At the beginning, a first path metric difference and a second path metric difference are generated according to the plurality of path metrics (step S960). Next, the positive values of the first and second path metric differences are determined (step S962). Next, a first logic signal is generated by comparing the positive first path metric difference with a threshold value and a second logic signal is generated by comparing the positive second path metric difference with the threshold value (step S964). Next, the first and second logic signals are selectively output according to the first and second decision bits to generate the erasure information (step S966).

As described in the above embodiment, the erasure unit 78 generates the erasure information for the decoder 80 using two path metric differences, namely, the first path metric difference S10 and the second path metric difference S11. However, the erasure unit 78 may also generate the erasure information using only one path metric difference, namely, the first path metric difference S10 (only first decision bit P0 required) or the second path metric difference S11 (only second decision bit P1 required). In such case, only half portion (e.g., the upper half portion or the half bottom portion in the figures) in each of the branch metric generator 72, the ACS unit 75, survivor path memory 76 and the erasure unit 78 is required to generate the erasure information and the Viterbi-decoded signal Viterbi_out. For example, the branch metric generator 72 may generate the branch metrics (Yi+1)² and Yi² after an input signal Yi is received, and the ACS unit 75 may generate the decision bit P0 and the first path metric difference S10 only using the branch metrics (Yi+1)² and Yi². The erasure unit 78 may also generate the erasure information using only the first path metric difference S10 and the first decision bit P0, and the survivor path memory 76 may generate the Viterbi-decoded signal Viterbi_out using only the first decision bit P0. More particular, in the upper half portion of the erasure unit 78, the logic signal L1 which is generated with reference to the first path metric difference S10 and the logic signal L2 which may be a reference logic value are both input into the selector 611. Based on the first decision bit P0, the selector 611 selects the logic signal L1 or the logic signal L2 as its output logic signal to be stored in the following register 601.

Alternatively, the branch metric generator 72 may generate the branch metrics (Yi−1)² and Yi² after an input signal Yi is received, and the ACS unit 75 may generate the decision bit P1 and the second path metric difference S11 only using the branch metrics (Yi−1)² and Yi². The erasure unit 78 may also generate the erasure information using only the second path metric difference S11 and the second decision bit P1, and the survivor path memory 76 may generate the Viterbi-decoded signal Viterbi_out using only the second decision bit P1. More particular, in the lower half portion of the erasure unit 78, the logic signal L2 which is generated with reference to the second path metric difference S11 and the logic signal L1 which may be a reference logic value are both input into the selector 612. Based on the second decision bit P1, the selector 612 selects the logic signal L2 or the logic signal L1 as its output logic signal to be stored in the following register 602.

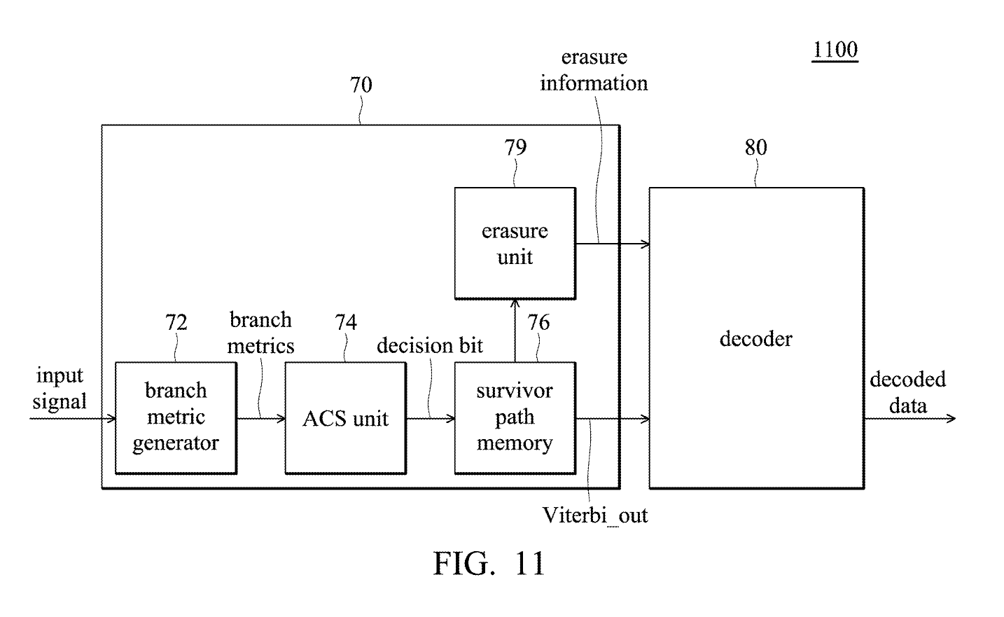

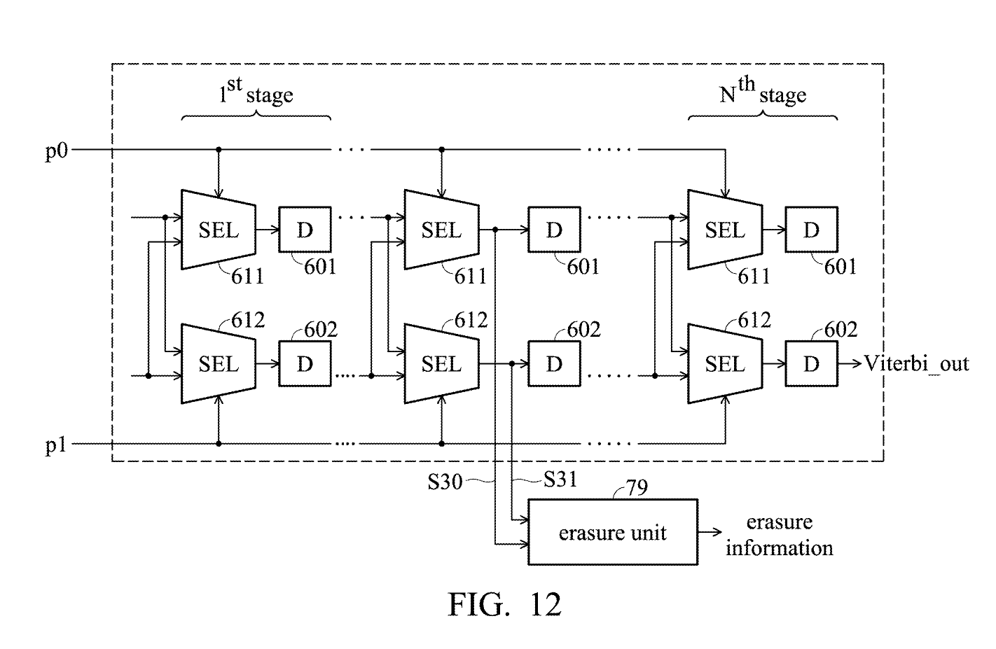

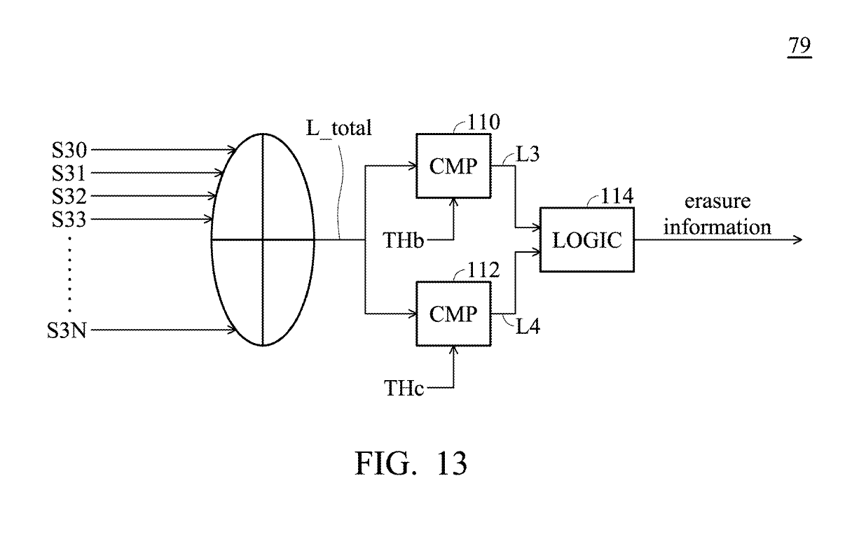

FIG. 11 depicts a diagram of an error-correcting apparatus used for decoding an input signal. The error-correcting apparatus 1100 comprises a Viterbi detector 70 and a decoder 80. The Viterbi detector 70 comprises a branch metric generator 72, an ACS unit 74, a survivor path memory 76 and an erasure unit 79. The functionality of the branch metric generator 72, the ACS unit 74 and the survivor path memory 76 are the same as the previous embodiment, so it is not described herein for brevity. The erasure unit 79 is coupled to the survivor path memory 76 in order to collect the related signals therefrom for generating erasure information, as described below. FIG. 12 depicts a detailed circuit diagram of a survivor path memory along with an erasure unit coupled thereto, according to an embodiment of the invention. In FIG. 12, the erasure unit 79 is coupled to a chosen selector stage and collects the output logic signals from the selectors of that stage. The chosen selector stage, where the logic signals are collected for the erasure unit 79, is preferably located in the intermediate portion of the plurality of stages. For example, if there are 10 selector stages within the survivor path memory 76, the erasure unit 79 may be coupled to a chosen stage out of the intermediate portion of the 10 stages to collect logic signals therefrom. The intermediate portion of the 10 stages may range from a 4^{th} to 6^{th} selector stage, or may even be the 3^{th} or 7^{th} stage. However, the selected stage must not be the very front or rear portion of the 10 selector stages, such as the 1^{st}, 2_{nd}, 9^{th} or 10^{th} stage. This is because in the front portion of the plurality of stages, the signal selection for a survivor path has yet to be converged, whereas in the last few stages, the signal selection for a survivor path has long been converged. Either case is undesired. The collected logic signals are processed to generate the erasure information, as described in FIG. 13. In FIG. 13, assume that there are logic signals S30 to S3N collected from the chosen selector stage, the logic value (1 or 0) of the logic signals are summed to obtain a total logic value L_total. In an embodiment, the total logic value L_total may be directly used to determine the erasure information, without the use of the comparators 110 and 112 and the logic gate 114. Specifically, the total logic value L_total may be directly compared with a threshold value. If the total logic value L_total is larger than the threshold value, the erasure information is output as logic high “1”, and vice versa. In another embodiment, the total logic value L_total may be compared with two thresholds THb and THc to determine the erasure information, as elaborated below. As shown in FIG. 13, a comparator 110 compares the total logic value L_total with a threshold value THb to generate a logic signal L3, and another comparator 112 compares the total logic value L_total with a threshold value THc to generate a logic signal L4. The logic gate 114 performs a logic operation of the logic signals L3 and L4 to obtain the erasure information. The operation of the logic gate 114 may be an OR operation in which the erasure information is output as logic high “1” as long as one of the logic signals L3 and L4 indicates logic high “1”, or may be an AND operation in which the erasure information is output as logic high “1” only if both logic signals L3 and L4 indicate logic high “1”, or may even be an XOR operation in which the erasure information is output as logic high “1” only if the logic signal L3 is different from the logic signal L4. For example, the threshold values THb and THc may be used to define a range of logic values, in which the total logic value L_total falling within the range is indicative of low data reliability of the Viterbi-decoded signal Viterbi_out. For example, the threshold value THb may be 6, the threshold value THc may be 4, and the logic operation of logic gate 114 may be an AND operation. In this regard, if the total logic value L_total is 5 which is higher than the threshold value THc but lower than the threshold value THb, then the logic signals L3 and L4 may both be logic high “1” and the erasure information is output as logic high “1”, indicating low data reliability of the Viterbi-decoded signal Viterbi_out.

As stated above, the erasure unit 79 may be coupled to a chosen stage out of the intermediate portion of the plurality stages to collect logic signals. The logic signals may be collected from the selectors 611 and 612 of that stage, or from the registers 601 and 602 of that stage.

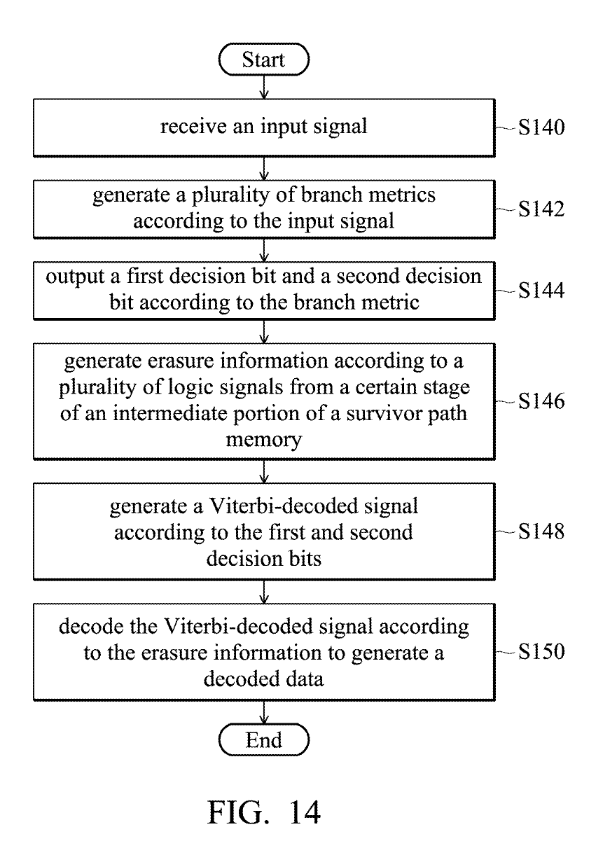

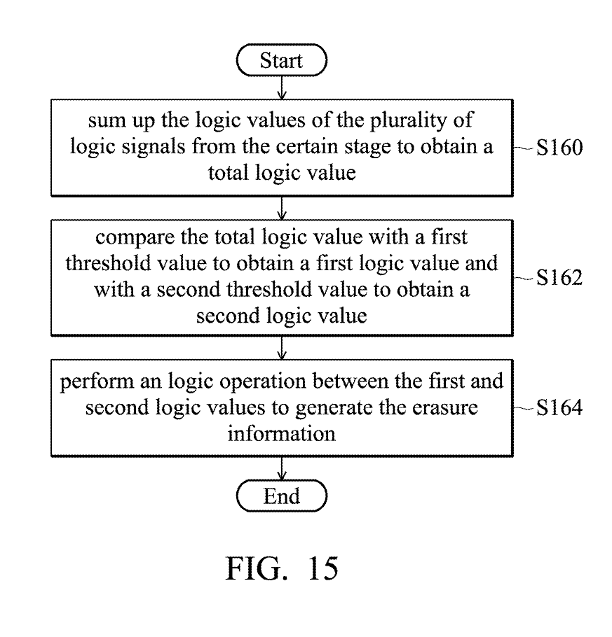

FIG. 14 depicts a flowchart of an error-correcting method used for decoding an input signal according to an embodiment of the invention, which is performed in accordance with the error-correcting apparatus shown in FIG. 11. At the beginning, an input signal is received (step S140). Next, a plurality of branch metrics are generated according to the input signal (step S142). Next, a first decision bit and a second decision bit are output according to the branch metrics (step S144). Next, erasure information is generated according to a plurality of logic signals from a chosen stage of an intermediate portion of a survivor path memory (step S146). Next, a Viterbi-decoded signal is generated according to the first and second decision bits (step S148). Next, the Viterbi-decoded signal is decoded according to the erasure information to generate a decoded data (step S150). FIG. 15 depicts a detailed flowchart of step S146 for generating the erasure information, according to an embodiment of the invention. At the beginning, the logic values of the plurality of logic signals from the chosen stage are summed to obtain a total logic value (step S160). The total logic value is compared with a first threshold value to obtain a first logic signal and compared with a second threshold value to obtain a second logic signal (step S162). Next, a logic operation between the first and second logic signals is performed to generate the erasure information (step S164).

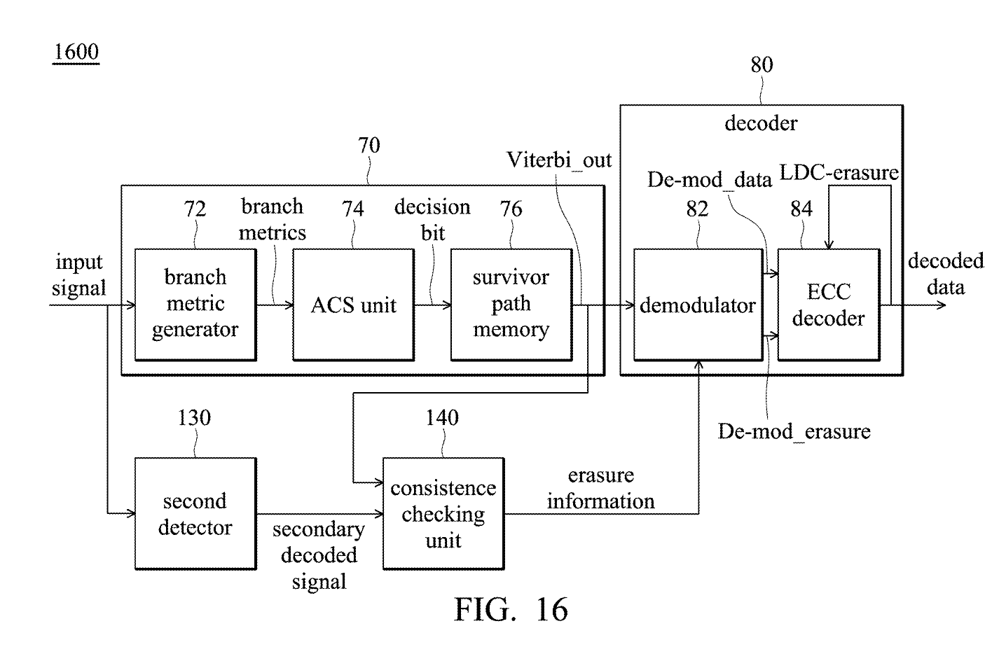

FIG. 16 depicts a diagram of an error-correcting apparatus used for decoding an input signal according to an embodiment of the invention. The error-correcting apparatus 1600 comprises a Viterbi detector 70, a decoder 80, a second detector 130 and a consistence checking unit 140. The Viterbi detector 70 comprises a branch metric generator 72, an ACS unit 74 and a survivor path memory 76. The decoder 80 comprises a demodulator 82 and an error-correcting code (ECC) decoder 84. The functionalities of the branch metric generator 72, ACS unit 74 and survivor path memory 76 are the same as previous embodiments, so it is not described herein for brevity. The Viterbi detector 70 decodes the input signal and outputs a Viterbi-decoded signal Viterbi_out (e.g., a first binary data) to the decoder 80 and the consistence checking unit 140. The second detector 130 is configured to decode the input signal to generate a secondary decoded signal (e.g., a second binary data). The consistence checking unit 140 is configured to generate erasure information by comparing the Viterbi-decoded signal Viterbi_out with the secondary decoded signal to find out the locations where inconsistencies between the Viterbi-decoded signal Viterbi_out and the secondary decoded signal has occurred. That is, if inconsistency occur on a bit (location) of the Viterbi-decoded signal Viterbi_out and the secondary decoded signal, the consistence checking unit 140 will generate erasure information by regarding the bit as an erasure bit. Based on this, the consistence checking unit 140 generates erasure information according to the comparison result. The decoder 80 then decodes the Viterbi-decoded signal Viterbi_out according to the erasure information.

The second detector 130 may be a slicer configured to generate the secondary decoded signal by slicing the input signal. In addition, the second detector 130 may also be a Viterbi detector which is the same as the Viterbi detector 70, but with different decoding parameters.

In FIG. 16 above, the decoder 80 comprises a demodulator 82 and an ECC decoder 84. In essence, the demodulator 82 is configured to convert the binary Viterbi-decoded signal Viterbi_out into a byte format and generates a demodulated data De_mod_data. During data demodulation, the demodulator 82 may also generate its own erasure information De_mod_erasure. The erasure information De_mod_erasure, along with the demodulated data De_mod_data, is sent to the ECC decoder 24 which decodes the demodulated data De_mod_data according to the erasure information De_mod_erasure. Here, by utilizing the consistence checking unit 140, error rate of the Viterbi-decoded signal Viterbi_out may be reduced.

In one embodiment, the erasure information generated by the consistence checking unit 140 may serve as the erasure information De_mod_erasure. In another embodiment, the erasure information generated by the erasure unit 78 may also serve as the erasure information De_mod_erasure (when the erasure unit 78 in FIG. 6 is configured in the Viterbi detector 70). Similarly, in still another embodiment, the erasure information generated by the erasure unit 79 may also serve as the erasure information De_mod_erasure (when the erasure unit 79 in FIG. 11 is configured in the Viterbi detector 70). In addition, in still another embodiment, a logic operation of the erasure information generated by the erasure unit 78 and the erasure information generated by the erasure unit 79 may also serve as the erasure information De_mod_erasure (when the erasure units 78 and 79 are both configured in the Viterbi detector 70). In addition, during the decoding phase of the ECC decoder 84, the ECC decoder 84 may also generate its own erasure information, called a long distance code (LDC) erasure information LDC_erasure. The erasure information LDC_erasure may be coupled back to the ECC decoder 84 to improve the decoding efficiency of the ECC decoder 84.

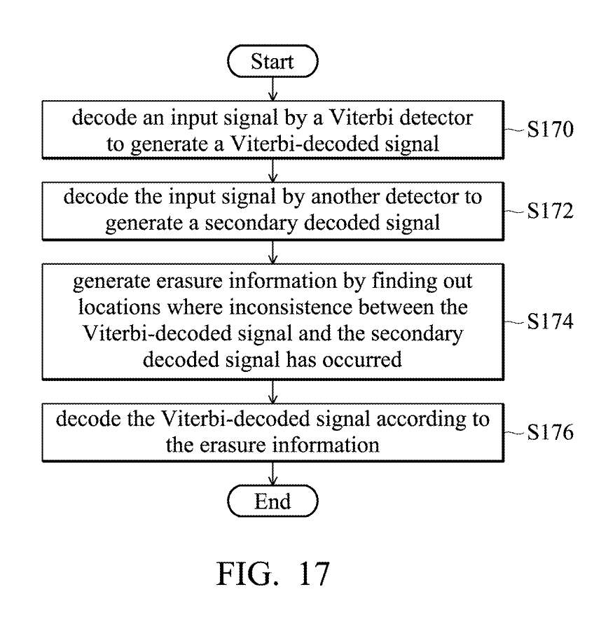

FIG. 17 depicts a flowchart of an error-correcting method used for decoding an input signal according to an embodiment of the invention, which is performed in accordance with the error-correcting apparatus shown in FIG. 16. At the beginning, an input signal is decoded by a Viterbi detector to generate a Viterbi-decoded signal (step S170). Next, the input signal is decoded by another detector to generate a secondary decoded signal (step S172). Next, erasure information is generated by finding out locations where inconsistencies between the Viterbi-decoded signal and the secondary decoded signal has occurred (step S174). Next, the Viterbi-decoded signal is decoded according to the erasure information (step S176).

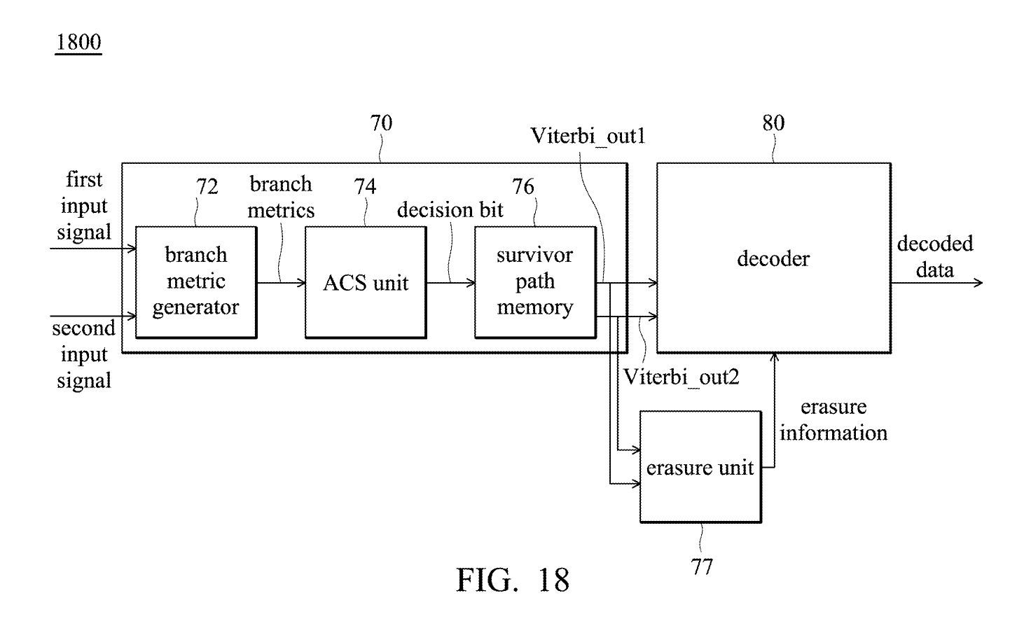

FIG. 18 depicts a diagram of an error-correcting apparatus used for decoding an input signal according to an embodiment of the invention. The error-correcting apparatus 1800 comprises a Viterbi detector 70 and a decoder 80. The Viterbi detector 70 comprises a branch metric generator 72, an ACS unit 74 and a survivor path memory 76. The functionalities of the branch metric generator 72, ACS unit 74 and survivor path memory 76 are the same as the previous embodiments, so it is not described herein for brevity. In FIG. 18, a predetermined location of an optical disk (such as the optical disk 10 in FIG. 1) is retrieved twice to obtain first and second input signals, and the Viterbi detector 70 is configured to decode the first and second input signals to respectively generate a first Viterbi-decoded signal Viterbi_out1 and a second Viterbi-decoded signal Viterbi_out2 (e.g., first and second binary data). The first Viterbi-decoded signal Viterbi_out1 and second Viterbi-decoded signal Viterbi_out2 are sent to an erasure unit 77. The erasure unit 77 generates erasure information by finding out locations where inconsistencies between the first Viterbi-decoded signal Viterbi_out1 and the second Viterbi-decoded signal Viterbi_out2 has occurred. That is, if inconsistency occur on a bit (location) of the first Viterbi-decoded signal Viterbi_out1 and the second Viterbi-decoded signal Viterbi_out2, the erasure unit 77 will generate erasure information by regarding the bit as an erasure bit. Based on this, the erasure unit 77 generates erasure information according to the comparison result. The decoder 80 then decodes the first Viterbi-decoded signal Viterbi_out1 and the second Viterbi-decoded signal Viterbi_out2 according to the erasure information and generates a decoded data.

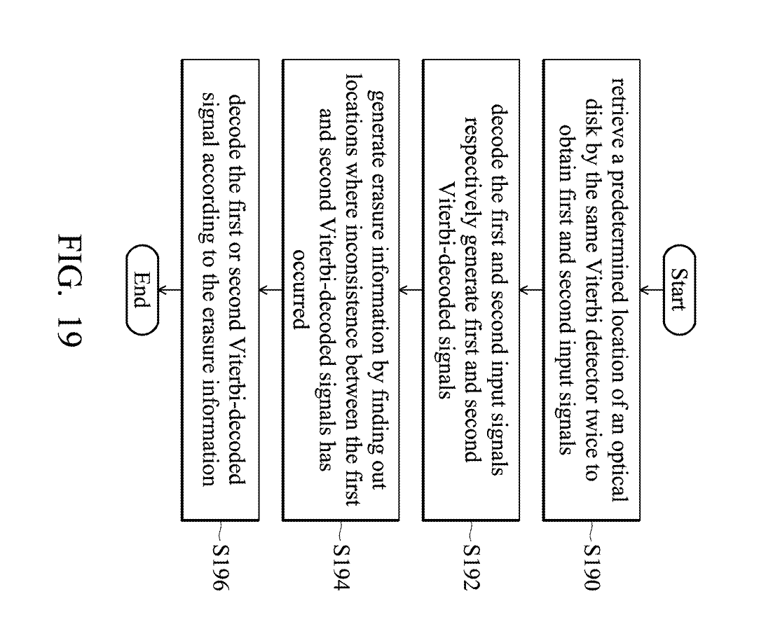

FIG. 19 depicts a flowchart of an error-correcting method used for decoding an input signal according to an embodiment of the invention, which is performed in accordance with the error-correcting apparatus shown in FIG. 18. At the beginning, a predetermined location of an optical disk is retrieved by the same Viterbi detector twice to obtain first and second input signals (step S190). Next, the first and second input signals are decoded to respectively generate first and second Viterbi-decoded signals (step S192). Next, erasure information is generated by finding out locations where inconsistencies between the first and second Viterbi-decoded signals has occurred (step S194). Next, a decoded data is generated by decoding the first or second Viterbi-decoded signal according to the erasure information (step S196).

As stated in the embodiment of FIG. 18, a predetermined location of an optical disk is retrieved twice to obtain first and second input signals. In another embodiment, however, the second input signal may be absent. In other words, the predetermined location of the optical disk is retrieved once to obtain a first input signal that is to be decoded by the Viterbi detector 70. In this regard, the Viterbi detector 70 may decode the input signal using first decoding parameters to generate a first Viterbi-decoded signal Viterbi_out1, and decode the input signal again using second decoding parameters different from the first decoding parameters to generate a second Viterbi-decoded signal Viterbi_out2. Then, the erasure unit 77 generates erasure information by finding out locations where inconsistencies between the first Viterbi-decoded signal Viterbi_out1 and the second Viterbi-decoded signal Viterbi_out2 has occurred. That is, if inconsistency occur on a bit (location) of the first Viterbi-decoded signal Viterbi_out1 and the second Viterbi-decoded signal Viterbi_out2, the erasure unit 77 will generate erasure information by regarding the bit as an erasure bit. Based on this, the erasure unit 77 generates erasure information according to the comparison result. The decoder 80 then decodes the first Viterbi-decoded signal Viterbi_out1 or the second Viterbi-decoded signal Viterbi_out2 according to the erasure information and generates a decoded data. In another embodiment, the first and second input signals may be used in another way to generate the erasure information. For example, the first input signal may be decoded to generate a first decoded data, with some bits corrected. Following, the second input signal may be decoded to generate a second decoded data, with some bits regarded as have low data reliability (sort of erasure bits). Then, the corrected bits in the first decoded data may be overwritten to the corresponding locations of the low data reliability bits of the second decoded data, if any, and the remaining low data reliability bits of the second decoded data are marked as erasure bits, thereby generating the erasure information.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An error-correcting apparatus for decoding an input signal by using a Viterbi algorithm to generate a Viterbi-decoded signal, comprising:
an erasure unit configured to generate at least one logic signal according to at least one path metric difference of path metrics in the Viterbi algorithm, and generate erasure information, wherein the erasure information indicates data reliability of at least one location of the Viterbi-decoded signal; and
a decoder configured to decode the Viterbi-decoded signal according to the erasure information.

2. The error-correcting apparatus as claimed in claim 1, wherein the erasure unit is configured to generate the erasure information by selectively outputting the at least one logic signal or a reference logic value according to the at least one decision bit.

3. The error-correcting apparatus as claimed in claim 2, further comprising:
an add-compare-select (ACS) unit configured to provide the at least one decision bit and the path metrics in the Viterbi algorithm.

4. The error-correcting apparatus as claimed in claim 3, further comprising:
a branch metric generator configured to generate branch metrics according to the input signal, such that the path metrics are generated according to the branch metrics by the ACS unit.

5. The error-correcting apparatus as claimed in claim 2, further comprising:
a survivor path memory unit configured to generate the Viterbi-decoded signal according to the least one decision bit.

6. The error-correcting apparatus as claimed in claim 2, wherein the erasure unit comprises:
a plurality of selector stages, each configured to selectively output the least one logic signal or a reference logic value according to the at least one decision bit.

7. The error-correcting apparatus as claimed in claim 1, wherein the erasure unit is configured to generate the at least one logic signal by comparing the at least one path metric difference with a predetermined threshold value.

8. The error-correcting apparatus as claimed in claim 7 wherein the at least one logic signal is logic high when the at least one path metric difference is smaller than the predetermined threshold value.

9. The error-correcting apparatus as claimed in claim 1, wherein the at least logic signal comprises a first logic signal and a second logic signal, the at least one path metric difference comprises a first path metric difference and a second path metric difference, and the erasure unit is configured to generate the first logic signal and the second logic signal according to the first path metric difference and second path metric difference, and generate the erasure information by selectively outputting the first logic signal or the second logic signal according to a first decision bit and a second decision bit.

10. The error-correcting apparatus as claimed in claim 9, further comprising:
an add-compare-select (ACS) unit configured to provide the first decision bit, the second decision bit and the path metrics in the Viterbi algorithm.

11. The error-correcting apparatus as claimed in claim 10, further comprising:
a branch metric generator configured to generate branch metrics according to the input signal, such that the path metrics are generated according to the branch metrics by the ACS unit.

12. The error-correcting apparatus as claimed in claim 9, further comprising:
a survivor path memory unit configured to generate the Viterbi-decoded signal according to the first decision bit and the second decision bit.

13. The error-correcting apparatus as claimed in claim 9, wherein the erasure unit is configured to generate the first logic signal by comparing the first path metric difference with a predetermined threshold value and generate the second logic signal by comparing the second path metric difference with the predetermined threshold value.

14. The error-correcting apparatus as claimed in claim 13, wherein the first logic signal is logic high when the first path metric difference is smaller than the predetermined threshold value and the second logic signal is logic high when the second path metric difference is smaller than the predetermined threshold value.

15. The error-correcting apparatus as claimed in claim 9, wherein the erasure unit comprises:
a plurality of selector stages, each configured to selectively output the first logic signal or the second logic signal according to the first decision bit and the second decision bit.

16. An error-correcting apparatus for decoding an input signal by using a Viterbi algorithm to generate a Viterbi-decoded signal, comprising:
an erasure unit configured to generate erasure information according to a plurality of logic signals from a chosen intermediate portion stage of a plurality of selector stages, and the erasure information indicates data reliability of at least one location of the Viterbi-decoded signal; and
a decoder configured to decode the Viterbi-decoded signal according to the erasure information.

17. The error-correcting apparatus as claimed in claim 16, wherein the plurality of logic signals are generated from a logic high signal and a logic low signal that are selectively output by the plurality of selector stages according to first and second decision bits.

18. The error-correcting apparatus as claimed in claim 17, wherein the erasure unit is further configured to calculate a summation of the logic signals, generate the first logic signal by comparing the summation with a low threshold value, generate the second logic signal by comparing the summation with a high threshold value, and perform a logic operation of the first logic signal and the second logic signal to generate the erasure information.

19. The error-correcting apparatus as claimed in claim 16, wherein the erasure unit is further configured to calculate a summation of the logic signals, and generate the erasure information by comparing the summation with a predetermined threshold value.

20. The error-correcting apparatus as claimed in claim 17, further comprising:
a survivor path memory unit having the plurality of selector stages and configured to generate the Viterbi-decoded signal with the plurality of selector stages according to the first and second decision bits.

21. The error-correcting apparatus as claimed in claim 20, further comprising:
a branch metric generator configured to generate branch metrics according to the input signal; and
an add-compare-select (ACS) unit configured to provide the first and second decision bits selecting the path metrics generated thereof, wherein the path metrics are generated according to the branch metrics.

22. An error-correcting apparatus, comprising:
a first detector configured to generate a first binary data according to an input signal;
a second detector configured to generate a second binary data according to the input signal;
a consistence check unit configured to generate erasure information by finding out at least one location where inconsistency between the first binary data and the second binary data has occurred, wherein the erasure information indicates data reliability of the at least one location of the first binary data; and
a decoder configured to decode the first binary data according to the erasure information.

23. The error-correcting apparatus as claimed in claim 22, wherein the first detector is a Viterbi detector configured to generate the first binary data by using a Viterbi algorithm, and the second detector is a slicer configured to generate the second binary data by slicing the input signal.

24. The error-correcting apparatus as claimed in claim 22, wherein the first and second detectors are Viterbi detectors configured to respectively generate the first and second binary data by using a Viterbi algorithm with different decoding parameters.

25. An error-correcting apparatus for data decoding of an optical disk, comprising:
a Viterbi detector configured to decode first and second input signals to generate first and second binary data;
an erasure unit configured to generate erasure information by finding out at least one location where inconsistency between the first and second binary data has occurred, wherein the erasure information indicates data reliability of the at least one location of the first and second binary data; and
a decoder configured to decode at least one of the first and second binary data according to the erasure information.

26. The error-correcting apparatus as claimed in claim 25, wherein the first and second input signals are data retrieved from a predetermined location of the optical disk twice.

27. The error-correcting apparatus as claimed in claim 25, wherein the first and second input signals are the same input signals, and the Viterbi detector is configured to generate the first and second binary data by using a Viterbi algorithm with different decoding parameters.
